(19) United States
(12) Patent Application Publication
(10) Pub. No.: US 2024/0421268 A1
(43) Pub. Date: Dec. 19, 2024

(54) QUANTUM DOT COLOR FILTER AND DISPLAY DEVICE

(71) Applicant: LITE-ON TECHNOLOGY CORPORATION, TAIPEI CITY (TW)

(72) Inventor: WEI-LING HUA, Taipei City (TW)

(21) Appl. No.: 18/741,211

(22) Filed: Jun. 12, 2024

Related U.S. Application Data
(60) Provisional application No. 63/472,621, filed on Jun. 13, 2023.

(30) Foreign Application Priority Data
May 9, 2024 (CN) 202410566239.9

(51) Int. Cl. H01L 33/50; H01L 25/075; H01L 33/44

(52) U.S. Cl. CPC H01L 33/505; H01L 25/0753; H01L 33/44

(57) ABSTRACT

A quantum dot color filter (QDCF) and a display device are provided. The display device includes the QDCF and a lighting module that includes multiple lighting chips. The QDCF includes a substrate, a light-shielding planarization layer, and a pixel layer, and has multiple pixels that correspond to the lighting chips. Each pixel includes a light-transmissive region and a light-shielding region. The light-shielding planarization layer is disposed on the substrate, and is configured to define the light-shielding region of the pixel. The pixel layer is disposed on the light-shielding planarization layer, and includes multiple pixel units. The pixel unit overlaps with the light-transmissive region, and partially overlaps with the light-shielding region of the pixel. In the pixel, an area of each pixel unit is greater than an area of each lighting chip along an orthogonal projection direction.

### CROSS-REFERENCE TO RELATED PATENT APPLICATION

This application claims the benefit of priorities to the U.S. Provisional Patent Application Ser. No. 63/472,621, filed on Jun. 13, 2023, and China Patent Application No. 202410566239.9, filed on May 9, 2024, in the People's Republic of China. The entire content of each of the above identified applications is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a color filter, and more particularly to a display device using a quantum dot color filter (QDCF).

### BACKGROUND OF THE DISCLOSURE

For a quantum dot color filter (QDCF) that is currently used in cooperation with a microLED, formation of a color filter layer is easily affected by a lower contour, thereby causing displacement of arrangement positions and the microLED not being fully covered by the color filter layer.

Therefore, how to overcome the above-mentioned deficiency through improvements in structural design has become one of the important issues to be solved in the related art.

### SUMMARY OF THE DISCLOSURE

In response to the above-referenced technical inadequacy, the present disclosure provides a quantum dot color filter (QDCF) that can prevent incomplete conversion of a display color caused by shifting.

In order to solve the above-mentioned problem, one of the technical aspects adopted by the present disclosure is to provide a quantum dot color filter (QDCF). The QDCF has a plurality of pixels that respectively correspond to a plurality of lighting chips of a lighting module, and each of the pixels includes a light-transmissive region and a light-shielding region. The QDCF includes a substrate, a light-shielding planarization layer, and a pixel layer. The light-shielding planarization layer is disposed on the substrate, and is configured to define the light-shielding region of each of the pixels. The pixel layer is disposed on the light-shielding planarization layer, and includes a plurality of pixel units. Each of the pixel units overlaps with the light-transmissive region, and partially overlaps with the light-shielding region of each of the pixels. In each of the pixels, a first area of each of the pixel units is greater than a second area of each of the lighting chips along an orthogonal projection direction.

In order to solve the above-mentioned problem, another one of the technical aspects adopted by the present disclosure is to provide a display device. The display device includes the above-mentioned QDCF and the lighting module. The lighting module is disposed on a light input side of the QDCF. The lighting module includes a circuit board, the lighting chips disposed on the circuit board, and one or more light-blocking structures disposed between any two adjacent ones of the lighting chips.

In order to solve the above-mentioned problem, yet another one of the technical aspects adopted by the present disclosure is to provide a display device, which includes a quantum dot color filter (QDCF) and a lighting module. The QDCF includes a light-shielding planarization layer and a pixel layer. The light-shielding planarization layer includes a plurality of transparent parts and a shielding part surrounding the plurality of transparent parts. The pixel layer is disposed on the light-shielding planarization layer, and includes a plurality of pixel units that correspond to the plurality of transparent parts. The pixel units include a plurality of red pixel units, a plurality of green pixel units, and a plurality of blue pixel units that are spaced apart from each other. Each of the red pixel units includes a red quantum dot layer, each of the green pixel units includes a green quantum dot layer, and each of the blue pixel units includes a transparent layer having diffusion particles. The lighting module is disposed on a light input side of the QDCF. The lighting module includes a circuit board, a plurality of lighting chips disposed on the circuit board, and one or more light-blocking structures disposed between any two adjacent ones of the lighting chips.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIGS. 1 and 2 are respectively schematic cross-sectional views of a display device and a QDCF according to a first embodiment of the present disclosure;

FIG. 3 is a schematic top view of the QDCF according to the first embodiment of the present disclosure;

FIGS. 4 and 5 are respectively schematic cross-sectional views of a display device and a QDCF according to a second embodiment of the present disclosure; and

FIGS. 6 and 7 are respectively schematic cross-sectional views of a display device and a QDCF according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

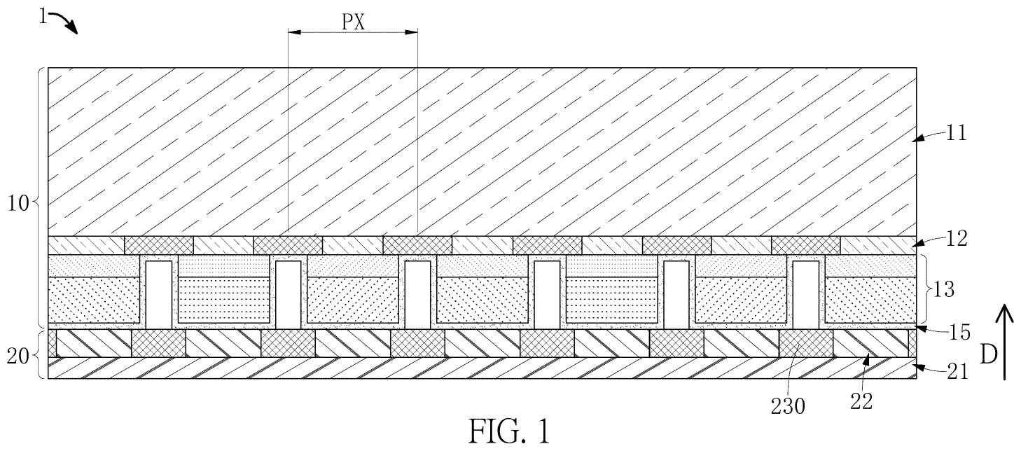

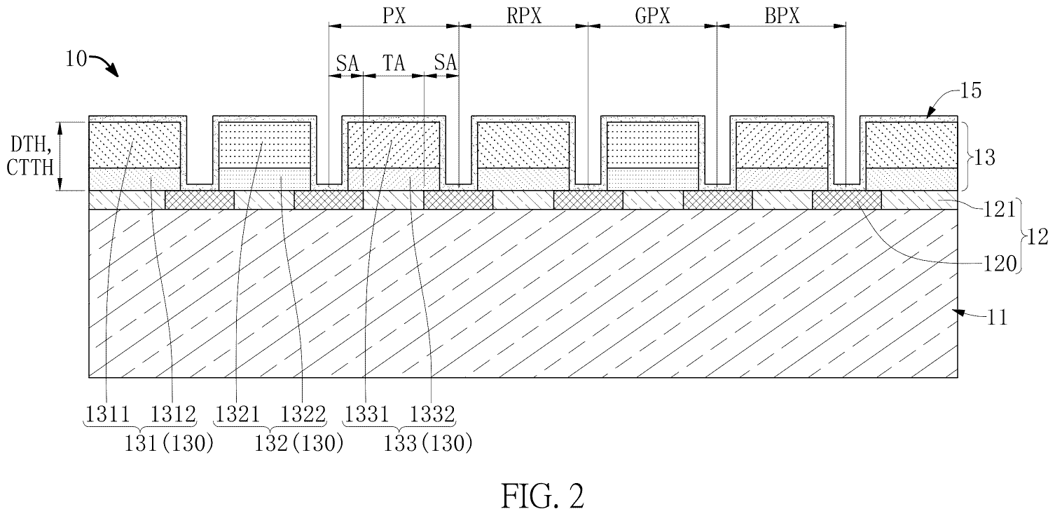

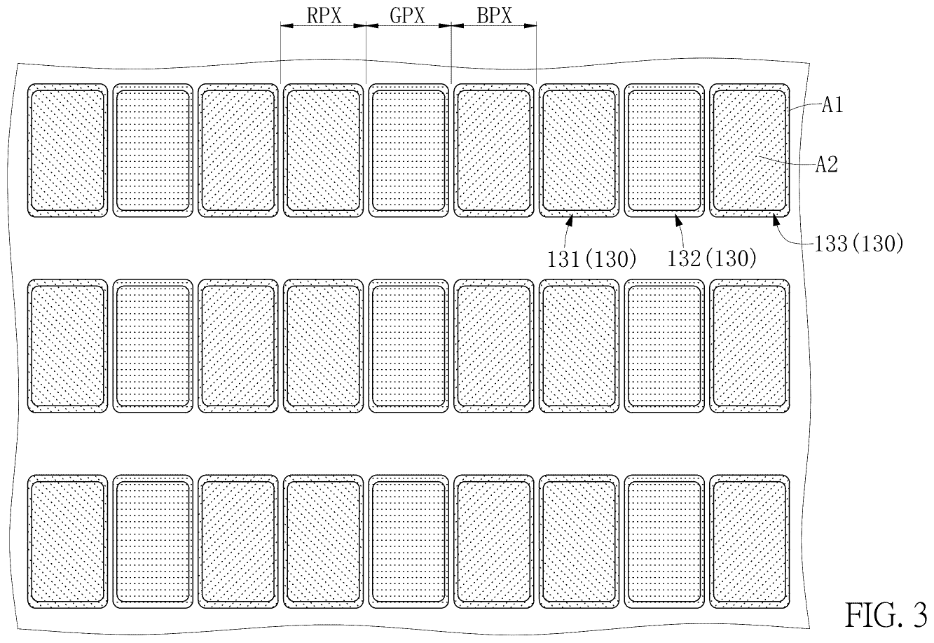

FIG. 1 is a schematic cross-sectional view of a display device according to a first embodiment of the present disclosure. FIG. 2 and FIG. 3 are respectively a schematic cross-sectional view and a schematic top view of a QDCF according to the first embodiment of the present disclosure.

Referring to FIG. 1 and FIG. 2, a display device 1 includes a quantum dot color filter (QDCF) 10 and a lighting module 20. The QDCF 10 is disposed on the lighting module 20, and includes a substrate 11, a light-shielding planarization layer 12, and a pixel layer 13. The QDCF 10 has a plurality of pixels PX, and the pixels PX are arranged in, for example, an array form. Each of the pixels PX corresponds to one of a plurality of lighting chips 22 of the lighting module 20. Each of the pixels PX includes a light-transmissive region TA and a light-shielding region SA. The light-transmissive region TA is surrounded by the light-shielding region SA, and is preferably positioned in a middle region of each of the pixels PX.

The substrate 11 is a transparent substrate, and can be selected from light-transmissive materials such as glass or plastics. The light-shielding planarization layer 12 is disposed on the substrate 11, and includes the light-transmissive regions TA and the light-shielding regions SA. In each of the pixels PX, a shielding part 120 is disposed to correspond to the light-shielding region SA, and a light-transmissive opening can be defined thereby. A transparent part 121 is formed in the light-transmissive opening, and corresponds to the light-transmissive region TA of the pixel PX. The shielding part 120 can block lights of different colors emitted by adjacent pixels. In the first embodiment, a transparent photoresist material is used as the transparent part 121. Since the transparent part 121 is filled in the light-transmissive opening formed by the shielding part 120, the light-shielding planarization layer 12 can have a flat surface, which is beneficial for subsequent coating and film formation. That is to say, a planarization surface allows the pixel layer 13 that is subsequently disposed on the light-shielding planarization layer 12 to be easily formed into a predetermined shape and not to be affected by a lower contour (especially when a large area is needed).

The shielding part 120 of the present embodiment is selected from materials having a high carbon black content, such as an oxide containing a black pigment. In particular, when 5% to 25% of carbon black particles are used in cooperation with a silicon oxide, a light-shielding effect can be enhanced. In order to overcome the problem of poor exposure for a film layer having a high percentage of carbon black, a lift-off process is used in the present embodiment for formation of the shielding part 120. In this way, a thickness of the shielding part 120 can be precisely controlled, thereby enhancing the light-shielding effect. In the lift-off process, one-time exposure and development is performed in cooperation with evaporation and peeling, such that the thickness of the shielding part 120 is precisely controlled to range between 0.1 μm and 3 μm (preferably between 0.5 μm and 2 μm). Preferably, a thickness of the transparent part 121 that is disposed adjacent to the shielding part 120 is the same as that of the shielding part 120. Accordingly, the light-shielding planarization layer 12 is formed, and also has a thickness ranging between 0.1 μm and 3 μm (preferably between 0.5 μm and 2 μm).

As shown in FIG. 2, the pixel layer 13 is disposed on the light-shielding planarization layer 12, and includes a plurality of pixel units 130 that respectively correspond in position to the pixels PX. In each of the pixels PX, a corresponding one of the pixel units 130 can overlap with the light-transmissive region TA and the light-shielding region SA at the same time. Specifically, in each of the pixels PX, the pixel unit 130 can completely cover a corresponding one of the light-transmissive regions TA, but only partially overlaps with the light-shielding region SA. Light emitted by the lighting module 20 can generate an expected color after absorption, conversion, or penetration through a corresponding one of the pixel units 130. The pixel units 130 in the pixel layer 13 include red pixel units 131, green pixel units 132, and blue pixel units 133, and their arrangement positions are shown in FIG. 2. The red pixel unit 131 corresponds to a red pixel RPX, the green pixel unit 132 corresponds to a green pixel GPX, and the blue pixel unit 133 corresponds to a blue pixel BPX. Each pixel unit is sequentially arranged in an array of the light-transmissive regions TA defined by the light-shielding planarization layer 12.

In detail, the red pixel unit 131 includes a red quantum dot layer 1311 and a red filter layer 1312 disposed between the red quantum dot layer 1311 and one of the transparent parts 121 of the light-shielding planarization layer 12. The green pixel unit 132 includes a green quantum dot layer 1321 and a green filter layer 1322 disposed between the green quantum dot layer 1321 and another one of the transparent parts 121 of the light-shielding planarization layer 12. The blue pixel unit 133 includes a white photoresist layer 1331 and a blue filter layer 1332 disposed between the white photoresist layer 1331 and yet another one of the transparent parts 121 of the light-shielding planarization layer 12.

For example, the red filter layer 1312 of the present disclosure includes propylene glycol monomethyl ether acetate (PGMEA) and a heterocyclic compound that contains a red pigment for filtering out a band of non-red light, such that light having a band of between 550 nm and 600 nm can penetrate through, and a red color is exhibited. The green filter layer 1322 includes propylene glycol monomethyl ether acetate (PGMEA) and a heterocyclic compound that contains a green pigment for filtering out a band of non-green light, such that light having a band of between 450 nm and 550 nm can penetrate through, and a green color is exhibited. The blue filter layer 1332 includes propylene glycol monomethyl ether acetate (PGMEA) and a heterocyclic compound that contains a blue pigment for filtering out a band of non-blue light, such that light having a band of between 350 nm and 450 nm can penetrate through, and a blue color is exhibited. In this way, the problem of a reduced display color gamut and color shift caused by a mixed output of blue light, red light, and green light can be effectively prevented.

Furthermore, the red quantum dot layer 1311 and the green quantum dot layer 1321 of the present disclosure each include II-VI, II-V, III-V, III-VI, IV, or IV-VI semiconductor materials. In an exemplary embodiment of the present disclosure, a particle size of particles in the red quantum dot layer 1311 ranges between 7 nm and 10 nm, and a particle size of particles in the green quantum dot layer 1321 ranges between 3 nm and 5 nm. In an exemplary embodiment of the present disclosure, a thickness of the pixel unit 130 ranges between 5 μm and 10 μm.

The lighting module 20 includes a plurality of blue lighting chips. In the blue pixel BPX, the blue pixel units 133 are set up, so that there is no need to change a wavelength of the blue light emitted by the lighting chip. In other words, there is no need to include a blue quantum dot layer. The blue light will directly pass through the transparent part 121 to reach the human eye. In the red pixel RPX and the green pixel GPX, the lights emitted from the lighting chips need to pass through corresponding color quantum dot layers (the same as the red pixel units 131 and the green pixel units 132), so as to be converted into the corresponding red and green lights before reaching the human eye. This results in the intensity of the blue light received by the human eye being much greater than the intensity of the red and green lights, thereby causing the overall color of the display device 1 not to achieve the ideal color balance. In the present embodiment, in order for the human eye to sense the similar intensity from the blue light and from each of the red light and the green light, the white photoresist layer 1331 is disposed on the blue filter layer 1332. After the blue light emitted by the lighting module 20 passes through diffusion particles in the transparent photoresist material, the human eye will receive blue light of the similar intensity as the red and green lights.

In each of the pixels PX, in a first direction D, an area of the pixel unit 130 is a first area A1, and a lighting area of the lighting chip 22 is a second area A2. As shown in FIG. 3, in each of the pixels PX, the first area A1 of the pixel unit 130 is greater than the second area A2.

Hence, the pixel unit 130 of the present disclosure completely covers the lighting chip 22, so as to ensure that light emitted by the lighting chip 22 is converted or absorbed by the pixel unit 130. For example, when an area size of the lighting chip 22 is 18×36 μm², the first area A1 of the pixel unit 130 can range between 30×50 μm² and 35×55 μm². Thus, the first area A1 of the pixel unit 130 is not less than 2 times and not greater than 3.5 times the second area A2 of the lighting chip 22 (preferably between 2.3 and 2.97). In addition, the shape of the pixel unit 130 is rounded rectangle.

A protective layer 15 is coated onto the pixel layer 13 by atomic layer deposition (ALD), so as to prevent water vapor in the environment from affecting the stability of a quantum dot material layer and prolong the service life of quantum dots. In the present embodiment, a gap is defined between any two adjacent ones of the pixel units 130, and a contour of the protective layer 15 is consistent with a surface contour of the pixel layer 13.

The QDCF 10 of the present embodiment is reversely attached to the lighting module 20, so as to form the display device 1. As shown in FIG. 1, the lighting module 20 of the present embodiment includes a circuit board 21, the lighting chips 22, and a plurality of light-blocking structures 230. The lighting chips 22 are disposed on the circuit board 21, and correspond in position to the pixels PX, respectively. For example, the lighting chips 22 can be arranged in a manner similar to the array form of the pixels PX, and correspond to the pixels PX in a one-to-one manner. The light-blocking structure 230 is disposed between any two adjacent ones of the lighting chips 22. That is, by surrounding the lighting chip 22, the light-blocking structures 230 only allow a light output region of the lighting chip 22 to be exposed. A first planarization top surface is formed by a top surface of the lighting chips 22 and a top surface of the light-blocking structures 230. In this embodiment, the light-blocking structure 230 is selected from dark-colored gel materials having a thickness the same as that of the lighting chips 22. The light-blocking structure 230 can be formed on the circuit board 21 by exposure and development, spraying and capillary action, molding, or lamination.

### Second Embodiment

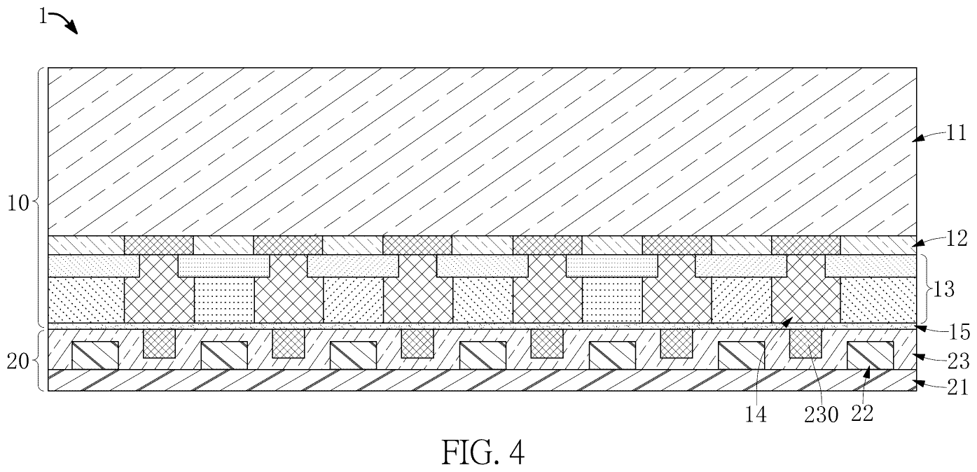

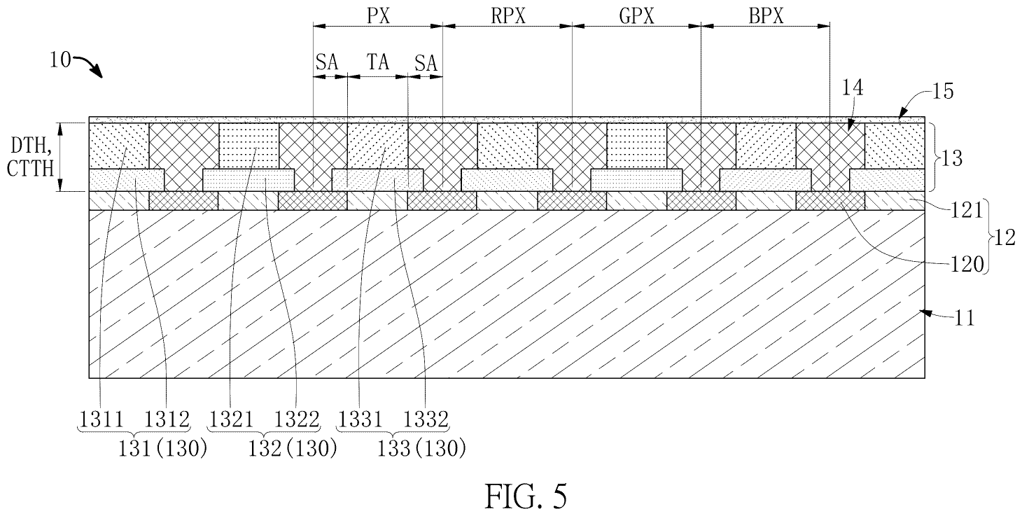

Referring to FIG. 4 and FIG. 5, a second embodiment of the present disclosure provides the QDCF 10, which includes the substrate 11, the light-shielding planarization layer 12, the pixel layer 13, and a partition 14. The pixel layer 13 and the partition 14 are jointly disposed on the light-shielding planarization layer 12. In addition, in each of the pixels PX, the partition 14 corresponds to the light-shielding region SA and surrounds the pixel unit 130.

Each of the red filter layer 1312, the green filter layer 1322, and the blue filter layer 1332 completely covers a corresponding one of the light-transmissive regions TA, i.e., being disposed on a corresponding one of the transparent parts 121 of the light-shielding planarization layer 12. The partition 14 is disposed to correspond to the shielding part 120. Then, the red quantum dot layer 1311, the green quantum dot layer 1321, and the white photoresist layer 1331 are disposed on the red filter layer 1312, the green filter layer 1322, and the blue filter layer 1332, respectively. That is, the partition 14 surrounds the red pixel unit 131, the green pixel unit 132, and the blue pixel unit 133. In this way, a planarization surface can be provided for coating of the protective layer 15.

The partition 14 is formed by photolithography, and can be selected from a white photoresist, a gray photoresist, a black photoresist, or a combination thereof (which can be light reflective or absorptive materials or a partially light-transmissive material). However, the present disclosure is not limited thereto. In the present embodiment, since a material having a low carbon black content is used as the partition 14, exposure thereof is easier as compared with the material having a high carbon black content. As such, a thickness of the partition 14 can be increased. A thickness DTH of the partition 14 is predetermined to be greater than or equal to a thickness CTTH of the pixel layer 13. That is to say, the thickness DTH of the partition 14 is greater than or equal to a total sum of a filter layer thickness and a quantum dot layer thickness. For example, the thickness of the partition 14 preferably ranges between 5 μm and 10 μm. In the pixel PX, a width of the partition 14 is less than or equal to a width of the shielding part 120. In FIG. 4, the partition 14 further partially covers the red filter layer 1312, the green filter layer 1322, and the blue filter layer 1332. Preferably, the red quantum dot layer 1311, the green quantum dot layer 1321, and the white photoresist layer 1331 each have a width the same as that of the transparent part 121, such that the width of the partition 14 is the same as that of the shielding part 120, and the thickness of the partition 14 is the same as that of the pixel layer 13. Accordingly, the light-shielding effect of the shielding part 120 can be effectively extended, and wavelengths of the red light, the green light, and the blue light can be blocked, so as to solve the problem of color crosstalk occurred to adjacent pixels.

As shown in FIG. 4, the lighting module 20 of the present embodiment includes the circuit board 21, the lighting chips 22, a transparent protective layer 23, and the light-blocking structures 230. The lighting chips 22 are disposed on the circuit board 21, and correspond in position to the pixels PX, respectively. A top surface of the lighting module 20 is the transparent protective layer 23, which exists between any two adjacent ones of the lighting chips 22. Furthermore, in the transparent protective layer 23, the light-blocking structures 230 are disposed to surround the lighting chips 22. The light-blocking structures 230 are formed on the transparent protective layer 23 by exposure and development, spraying and capillary action, molding, or lamination. In the present embodiment, a lamination structure is provided, which has a double layer with a transparent layer, a light-blocking layer, and a carrier stacked in a sequential manner or in an alternate manner. Then, the lamination structure is flipped and pressed on the lighting chips 22 and the circuit board 21 to form the lighting module 20. Thus, the lighting chips 22 and the circuit board 21 are directly covered by the transparent layer (as the transparent protective layer 23), and one or more accommodating spaces are concavely formed on a surface of the transparent protective layer 23 between any two adjacent ones of the lighting chips 22. The light-blocking layer is filled in the accommodating spaces, and is correspondingly arranged at a periphery of the lighting chips 22 (as the light-blocking structure 230). The thickness of the light-blocking structure 230 is greater than or equal to a thickness of the transparent protective layer 23, and needs to be greater than or equal to one-half a thickness of the lighting chip 22. For example, the light-blocking structure 230 is selected from dark-colored gel materials having a thickness of between 4 μm and 6 μm. Hence, in the present embodiment, the transparent protective layer 23 can effectively improve luminance, and the light-blocking structures 230 arranged at the periphery of the lighting chips 22 can prevent the interference problem. A second planarization top surface is formed by a top surface of the transparent protective layer 23 and the top surface of the light-blocking structures 230, which is beneficial for the assembly of the lighting module 20 and the QDCF 10. In addition, in other configurations, the second planarization top surface can also be formed by the lighting chips 22 and the top surface of the transparent protective layer 23. The light-blocking structures 230 are arranged around side surfaces of the lighting chips 22, and the transparent protective layer 23 is disposed thereon. After its completion, the QDCF 10 can be reversely attached to the lighting module 20, so as to form the display device 1.

### Third Embodiment

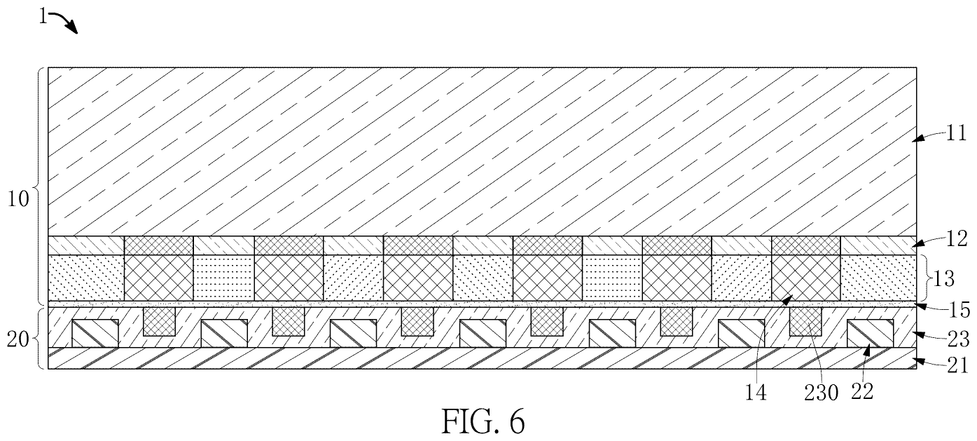

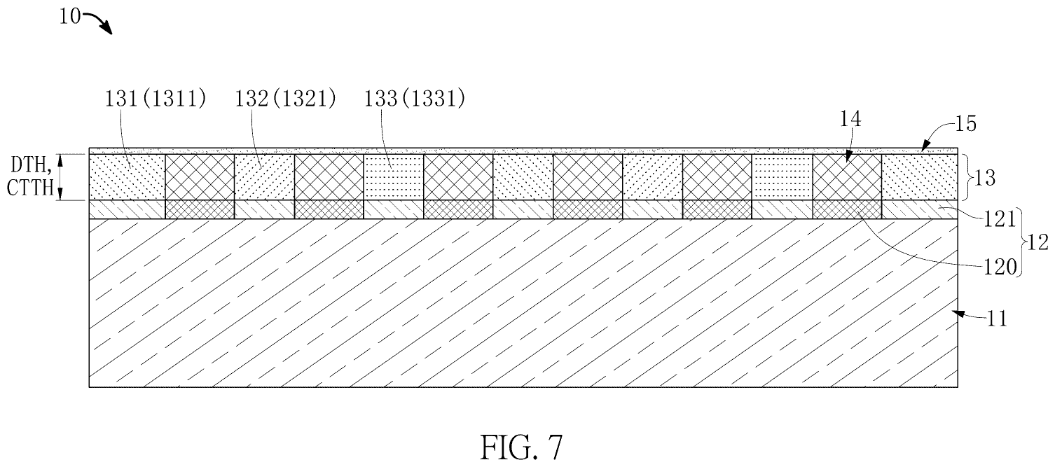

FIG. 6 is a schematic cross-sectional view of the display device according to a third embodiment of the present disclosure, and FIG. 7 is a schematic cross-sectional view of the QDCF according to the third embodiment of the present disclosure.

A third embodiment of the present disclosure provides the display device 1. As shown in FIG. 6, in the display device 1, the light-shielding planarization layer 12 is formed on the substrate 11. The transparent photoresist material (e.g., a yellow photoresist material) used as the transparent part 121 of the light-shielding planarization layer 12 can further filter out light between 400 nm and 500 nm, and thus the blue light that is emitted by the lighting chip and does not excite a quantum dot material can be effectively filtered. In this way, excessive blue light can be effectively removed. In an exemplary embodiment of the present disclosure, the transparent photoresist material is a mixture of propylene glycol monomethyl ether acetate, a polyacrylic acid resin, and bismuth vanadium oxide. Here, a weight percentage of the bismuth vanadium oxide ranges between 5% and 20%. Apart from having a good adhesive force to a glass substrate, the transparent photoresist material is capable of filtering out the blue light. In addition, since the yellow photoresist material is used in the third embodiment, a filter layer can be omitted from subsequent manufacturing processes. The red quantum dot layer 1311, the green quantum dot layer 1321, and the white photoresist layer 1331 can be directly formed on the light-shielding planarization layer 12, such that a number of manufacturing steps and production costs can be reduced, and productivity can be improved.

### Beneficial Effects of the Embodiments

In conclusion, in the display device that includes the QDCF provided by the present disclosure, since a coverage area of the quantum dot layer and the filter layer is greater than a light output area of the lighting chip (as compared with a conventional color filter), the quantum dot layer and the filter layer can completely cover the lighting chip.

Furthermore, when the QDCF is being aligned with a machine during the exposure and development process, shifting may occur, thereby causing the quantum dot layer and the filter layer to be out of alignment with the lighting chip. However, since the coverage area of the quantum dot layer and the filter layer is greater than the light output area of the lighting chip, the light emitted by the lighting module 20 can still be absorbed or converted by a corresponding one of the pixel units 130, so as to generate an expected display color.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A quantum dot color filter (QDCF), wherein the QDCF has a plurality of pixels that respectively correspond to a plurality of lighting chips of a lighting module, and each of the pixels includes a light-transmissive region and a light-shielding region, the QDCF comprising:
a substrate;
a light-shielding planarization layer disposed on the substrate, wherein the light-shielding planarization layer is configured to define the light-shielding region of each of the pixels; and
a pixel layer disposed on the light-shielding planarization layer and including a plurality of pixel units, wherein each of the pixel units overlaps with the light-transmissive region, and partially overlaps with the light-shielding region of each of the pixels;
wherein, in each of the pixels, a first area of each of the pixel units is greater than a second area of each of the lighting chips along an orthogonal projection direction.

2. The QDCF according to claim 1, wherein the light-shielding planarization layer includes:
a shielding part, wherein the shielding part is disposed to define a plurality of light-transmissive openings; and
a plurality of transparent parts, wherein the transparent parts are respectively formed in the light-transmissive openings to correspond to the light-transmissive regions.

3. The QDCF according to claim 2, wherein each of the transparent parts includes a transparent photoresist material.

4. The QDCF according to claim 3, wherein the transparent photoresist material filters out light between 400 nm and 500 nm.

5. The QDCF according to claim 4, wherein the transparent photoresist material includes propylene glycol monomethyl ether acetate, a polyacrylic acid resin, and bismuth vanadium oxide.

6. The QDCF according to claim 3, further comprising a partition, wherein the partition is disposed on the light-shielding planarization layer, corresponds to the light-shielding region, and surrounds each of the pixel units.

7. The QDCF according to claim 6, wherein a thickness of the partition is greater than or equal to a thickness of the pixel layer, and a width of the partition is less than or equal to a width of the shielding part.

8. The QDCF according to claim 6, wherein the partition includes a white photoresist, a gray photoresist, a black photoresist, or a combination thereof.

9. The QDCF according to claim 3, wherein the pixel units include a plurality of red pixel units, a plurality of green pixel units, and a plurality of blue pixel units; wherein each of the red pixel units includes a red quantum dot layer, each of the green pixel units includes a green quantum dot layer, and each of the blue pixel units includes a white photoresist layer.

10. The QDCF according to claim 9, wherein each of the red pixel units further includes a red filter layer, each of the green pixel units further includes a green filter layer, and each of the blue pixel units further includes a blue filter layer; wherein, in each of the pixel units, an area of a color filter layer is not less than an area of a quantum dot layer.

11. The QDCF according to claim 9, wherein a particle size of particles in the red quantum dot layer ranges between 7 nm and 10 nm, and a particle size of particles in the green quantum dot layer ranges between 3 nm and 5 nm.

12. The QDCF according to claim 1, further comprising a protective layer disposed on the pixel layer.

13. The QDCF according to claim 1, wherein the first area is within a range from 2 times to 3.5 times the second area.

14. A display device, comprising:
the QDCF as claimed in claim 1; and
the lighting module disposed on a light input side of the QDCF, wherein the lighting module includes:
a circuit board;
the lighting chips disposed on the circuit board; and
one or more light-blocking structures disposed between any two adjacent ones of the lighting chips.

15. The display device according to claim 14, wherein a first planarization top surface is formed by a top surface of the lighting chips and a top surface of the light-blocking structures.

16. The display device according to claim 14, wherein the lighting module further includes a transparent protective layer disposed between any two adjacent ones of the lighting chips, the light-blocking structures are disposed on or under the transparent protective layer, and a second planarization top surface is formed by a top surface of the transparent protective layer and a top surface of the light-blocking structures or a top surface of the lighting chips.

17. A display device, comprising:
a quantum dot color filter (QDCF), wherein the QDCF includes:
a light-shielding planarization layer, wherein the light-shielding planarization layer includes a plurality of transparent parts and a shielding part surrounding the plurality of transparent parts; and
a pixel layer disposed on the light-shielding planarization layer and including a plurality of pixel units that correspond to the plurality of transparent parts, wherein the pixel units include a plurality of red pixel units, a plurality of green pixel units, and a plurality of blue pixel units that are spaced apart from each other;
wherein each of the red pixel units includes a red quantum dot layer, each of the green pixel units includes a green quantum dot layer, and each of the blue pixel units includes a transparent layer having diffusion particles; and
a lighting module disposed on a light input side of the QDCF, wherein the lighting module includes:
a circuit board;
a plurality of lighting chips disposed on the circuit board; and
one or more light-blocking structures disposed between any two adjacent ones of the lighting chips.

18. The display device according to claim 17, wherein the QDCF further includes a partition disposed on the shielding part of the light-shielding planarization layer and surrounding each of the pixel units, a material of the partition and a material of the shielding part are different from each other, and a thickness of the partition is greater than a thickness of the shielding part.

19. The display device according to claim 17, wherein each of the transparent parts includes a transparent photoresist material or a yellow photoresist material.

20. The display device according to claim 17, wherein the lighting module further includes a transparent protective layer disposed between any two adjacent ones of the lighting chips, the light-blocking structures are disposed on or under the transparent protective layer, and a second planarization top surface is formed by a top surface of the transparent protective layer and a top surface of the light-blocking structures or a top surface of the lighting chips.
